(19) United States
(12) Patent Application Publication
(10) Pub. No.: US 2006/0138670 A1
(43) Pub. Date: Jun. 29, 2006

(54) Method of forming copper line in semiconductor device

(76) Inventor: June Woo Lee, Osan-city (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(21) Appl. No.: 11/319,341

(22) Filed: Dec. 27, 2005

(30) Foreign Application Priority Data
Dec. 24, 2004 (KR) 10-2004-0112060

(51) Int. Cl. H01L 21/44; H01L 23/48

(52) U.S. Cl. 257/762; 438/687; 438/682

(57) ABSTRACT

A method of forming a copper line in a semiconductor device may enhance reliability of the copper line. The method includes the steps of forming a trench in a substrate; forming a copper layer filling the trench; planarizing the copper layer with respect to the trench; annealing the planarized copper layer; and forming a silicide layer in a surface region of the planarized copper layer.

This application claims the benefit of Korean Patent Application No. 10-2004-0112060, filed on Dec. 24, 2004, which is hereby incorporated by reference as if fully set forth herein.

### BACKGROUND OF THE INVENTION

1. Field of the Invention

The present invention relates to semiconductor devices, and more particularly, to a method of forming a copper line in a semiconductor device. Although the present invention is suitable for a wide scope of applications, it is particularly suitable for enhancing reliability of the line.

2. Discussion of the Related Art

An interconnection in a semiconductor device is widely formed from a metal layer of, for example, aluminum, an aluminum alloy, or tungsten, exhibiting a low melting point or a relatively high specific resistance. Highly integrated semiconductor devices, however, now tend to employ a highly conductive material such as copper, gold, silver, cobalt, chromium, or nickel as the material of a wiring layer. Popular among these are copper and copper alloys, which exhibit a low specific resistance, high reliability in terms of electro-migration and stress-migration, and a relatively low cost. Also, the lower intrinsic resistivity of a conventional copper line compared to an aluminum line provides a reduced RC delay and thus enables its applicability to devices having design rules under 0.13 μm.

The thermal expansion coefficient of a line formed of copper (Cu), however, is about ten times that of a dielectric layer typically juxtaposed to (or surrounding) the copper line, generating a compressive stress that accumulates during the processing of semiconductor device fabrication. Thus, due to the compressive stress, the high thermal expansion coefficient (among other reasons) tends to generate hillocks, which adversely affects the fabrication process and, in turn, degrades device reliability. To reduce this influence on a fabrication process, stresses generated during or resulting from Cu electro-chemical plating can be relieved by a subsequent annealing step. Meanwhile, however, stress may also be generated by a planarization process, such as chemical-mechanical polishing, typically performed on a thickly formed copper layer in semiconductor processing. Unless the stress is relieved, stress migration can occur in subsequent process steps, which can lead to hillock and void formation.

### SUMMARY OF THE INVENTION

Accordingly, the present invention is directed to a method of forming a copper line in a semiconductor device that substantially obviates one or more problems due to limitations and disadvantages of the related art.

An object of the present invention is to provide a method of forming a copper line in a semiconductor device, which enhances the reliability of the copper line.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages in accordance with the purpose of the invention, as embodied and broadly described herein, there is provided a method of forming a copper line in a semiconductor device, the method comprising forming a trench in a substrate; forming a copper layer filling the trench; planarizing the copper layer with respect to the trench; annealing the planarized copper layer; and forming a silicide layer in a surface region of the planarized copper layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIGS. 1A-1D are cross-sectional diagrams of a copper line in a semiconductor device according to the present invention.

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

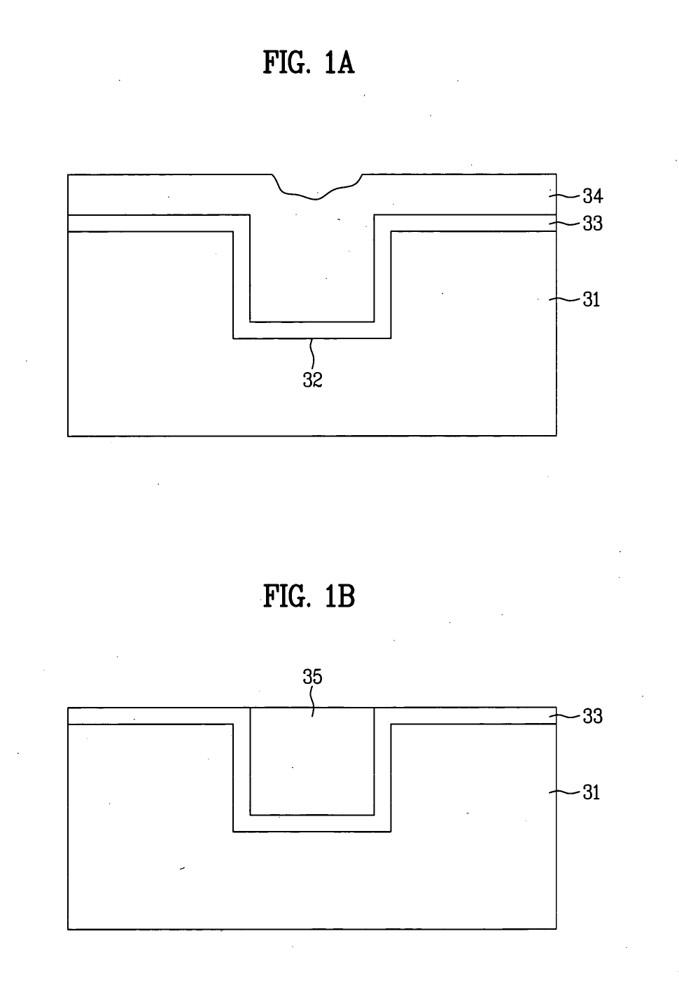

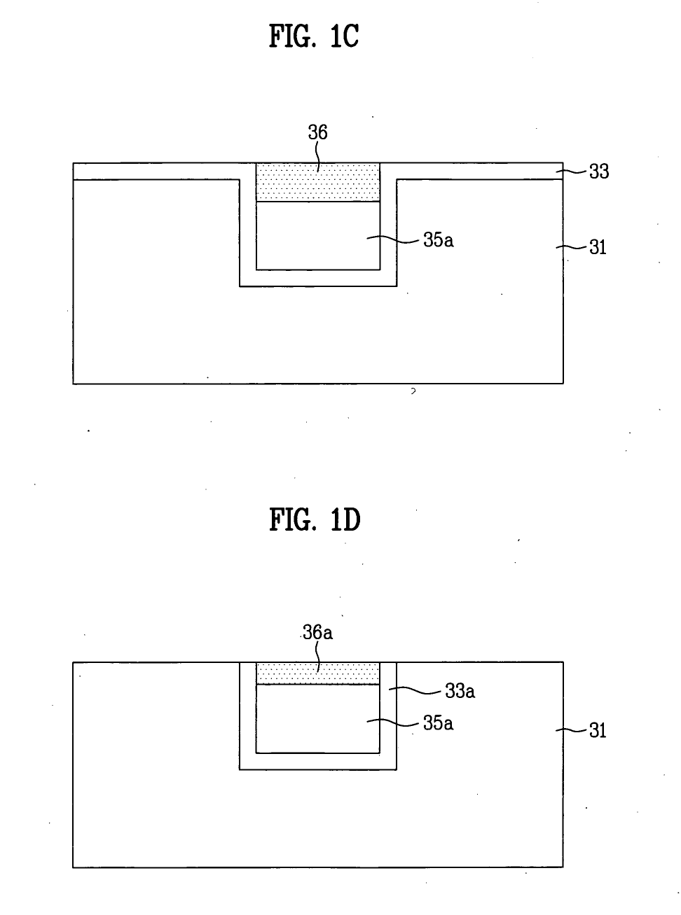

FIGS. 1A-1D respectively illustrate sequential process steps of a method of forming a copper line in a semiconductor device according to the present invention.

Referring to FIG. 1A, a trench 32 is formed to a desired depth by selectively removing a predetermined portion of a substrate 31 using photolithography. The substrate 31 may be an insulating interlayer formed, as a dielectric layer, on a semiconductor substrate (not shown), and the trench 31 may be formed in conjunction with a via hole or contact hole as part of a damascene or dual damascene process. A barrier film 33 comprising a conductive material (a barrier layer) is formed on an entire surface of the substrate 31, specifically including in the trench 32, by depositing a thin layer of, for example, titanium nitride (TiN), tantalum (Ta), tantalum nitride (TaN), a tungsten nitride (WNₓ), a titanium aluminide (TiAl_{y}, where y is typically about 3), or titanium aluminum nitride (TiAl_{w}N_{z}), to a thickness of ˜10˜1,000 Å using chemical vapor deposition (CVD) or physical vapor deposition (PVD). Thus, the barrier layer may be formed by blanket deposition or conformal deposition. Prior to forming the barrier layer, a thin adhesive layer (e.g., Ti, Ta or other conductive material providing an adhesive function) may be conformally deposited onto the substrate and in the trench. A copper layer 34 is then thickly formed over the substrate 31, including the barrier film 33, by CVD and/or electroplating (e.g., first by depositing a thin Cu seed layer by CVD, then depositing a bulk Cu layer by electroplating) to deposit a stable and clean Cu layer over the barrier film and in the trench 32. Thus, the barrier film 33 serves to prevent diffusion into the substrate 31 of copper (Cu) atoms from the copper layer 34 (and, to the extent necessary and/or desired, of atoms such as oxygen from the substrate 31 into the copper layer 34).

The copper line of the present invention may be formed by depositing a barrier metal layer and a Cu seed layer in a PVD or CVD chamber and then performing the copper electroplating in a Cu electroplating instrument. Besides electroplating, the copper layer 34 of the present invention may also be formed by metal-organic chemical vapor deposition at a deposition temperature of 50˜300° C. using 5˜100 sccm of a precursor including a mixture of (hfac)CuTMVS and an additive, a mixture of (hfac)CuVTMOS and an additive, or a mixture of (hfac)Cu(PENTENE) and an additive. That is, the copper layer 34 is formed by depositing (electroplating) copper on a Cu seed layer that was formed by metal-organic chemical vapor deposition, with the electroplating being performed at a temperature of −20° C. to +150° C. (that may be lower than the temperature at which the seed layer was formed). Alternatively, when the bulk Cu layer is formed by MO-CVD, it can be done in the same chamber, without breaking vacuum after forming the Cu seed layer.

Referring to FIG. 1B, chemical-mechanical polishing is performed to for planarize the copper layer 34. The barrier film 33 may serve or function as a polishing stop layer (and thus may comprise a layer or material that has a polishing rate significantly lower than that of the copper layer 34, perhaps one-third, one-fifth, one-tenth, one-twentieth or less of the polishing rate of the copper layer 34 under the conditions of polishing the copper layer 34), thereby forming a copper line 35. That is, after planarization to remove an excess deposition of copper, which fills the trench 32 and overlies other areas of the substrate 31 after the process step of FIG. 1A, the material of the copper line 35 remains only in the trench, flush with the upper surface of the barrier film 33 or the substrate 31.

Referring to FIG. 1C, the copper line 35 is annealed in an ambient comprising or consisting essentially of nitrogen (N₂). Annealing can be conducted at a temperature of 150˜300° C. Such annealing may passivate or incorporate small amounts of nitrogen into the surface of the copper line 35, and thus, produce a nitrided copper line 35 and/or copper silicide 36/36a. Subsequently, silicidation is carried out on a surface of the copper line 35, in an ambient comprising silane (SiH₄), to form a silicide layer 36 in an upper region of a copper line 35a. The ambient in either or both of the annealing and/or silicidation steps can further comprise an inert gas, such as He, Ne, Ar, (in the case of silicidation) N₂, etc., and/or a reducing gas such as N₂, H₂, NH₃, N₂H₄, etc. The silicide layer 36 prevents an oxidation of the copper's surface.

Referring to FIG. 1D, the barrier metal layer 33 and the silicide layer 36 are planarized, generally using an upper surface of the semiconductor substrate 31 as a polishing stop layer. In this case, the upper surface of the semiconductor substrate 31 may comprise a material or layer having a polishing rate significantly lower than that of the silicide 36 and/or the barrier layer 33, perhaps one-third, one-fifth, one-tenth, one-twentieth or less of the polishing rate of the silicide 36 and/or the barrier layer 33 under the polishing conditions employed. Hence, the Cu line 35a, having a planarized surface including a planarized silicide layer 36a, is left in the trench 32 atop a planarized barrier film 33a.

According to the present invention, since annealing is carried out after the copper line (e.g., copper line 35, prior to silicidation and/or barrier layer CMP) has been chemical-mechanical polished, stress may be relieved and/or the reliability of the line may be enhanced. In addition, since a silicide layer is formed on the surface of the copper line, oxidation of the copper metallization may be inhibited and/or prevented, and the reliability of the line can be further enhanced.

It will be apparent to those skilled in the art that various modifications can be made in the present invention without departing from the spirit or scope of the invention. Thus, it is intended that the present invention covers such modifications provided they come within the scope of the appended claims and their equivalents.

What is claimed is:

1. A method of forming a copper line in a semiconductor device, comprising:
forming a trench in a substrate;
forming a copper layer filling the trench;
planarizing the copper layer with respect to the trench;
annealing the planarized copper layer; and
forming a silicide layer in a surface region of the planarized copper layer.

2. The method of claim 1, wherein forming the silicide layer comprises siliciding the annealed copper layer in an ambient comprising silane (SiH₄).

3. The method of claim 1, further comprising:
forming a barrier film on an entire surface of the substrate including in the trench,
wherein the copper layer is formed on the barrier film.

4. The method of claim 3, wherein said planarizing comprises chemical-mechanical polishing.

5. The method of claim 4, wherein the barrier film comprises a polishing stop layer.

6. The method of claim 3, wherein the barrier film comprises at least one member selected from the group consisting of titanium nitride (TiN), tantalum (Ta), tantalum nitride (TaN), a tungsten nitride (WNₓ), a titanium aluminide (TiAl_{y}), and titanium aluminum nitride (TiAl_{w}N_{z}).

7. The method of claim 6, wherein the barrier film has a thickness of 10˜1,000 Å, and forming the barrier film comprises one of chemical vapor deposition and physical vapor deposition.

8. The method of claim 1, wherein the substrate comprises a dielectric layer.

9. The method of claim 8, wherein the substrate comprises an insulating interlayer.

10. The method of claim 1, further comprising:
planarizing the silicide layer using a surface of the substrate as a polishing stop layer.

11. The method of claim 1, wherein said annealing is performed in an ambient comprising nitrogen (N₂).

12. The method of claim 11, wherein said annealing is performed at a temperature of 150˜300° C.

13. The method of claim 1, wherein forming the copper film comprises at least one selected from a group consisting of electroplating, chemical vapor deposition, physical vapor deposition, and metal-organic chemical vapor deposition.

14. A semiconductor device, comprising:
a dielectric layer having a trench;
a planarized copper layer filling the trench;
a silicide layer in a surface region of said planarized copper layer.

15. The device of claim 14, wherein said planarized copper layer comprises a nitrogen (N₂)-annealed copper layer.

16. The device of claim 15, wherein said silicide layer comprises a copper silicide.

17. The device of claim 14, further comprising:
a barrier film in a bottom of the trench,
wherein said planarized copper layer is on said barrier film.

18. The method of claim 17, wherein said barrier film comprises at least one member selected from the group consisting of titanium nitride (TiN), tantalum (Ta), tantalum nitride (TaN), a tungsten nitride (WNₓ), a titanium aluminide (TiAl_{y}), and titanium aluminum nitride (TiAl_{w}N_{z}),

19. The method of claim 18, wherein said barrier film has a thickness of 10˜1,000 Å, and forming said barrier film comprises one of chemical vapor deposition and physical vapor deposition.

20. The method of claim 14, wherein said silicide layer comprises a planarized silicide layer.
